(19) United States
(12) Patent Application Publication
(10) Pub. No.: US 2011/0037046 A1
(43) Pub. Date: Feb. 17, 2011

(54) RESISTANCE-CHANGE MEMORY AND METHOD OF MANUFACTURING THE SAME

(76) Inventors: Mitsuru SATO, Kuwana-shi (JP); Kohichi Kubo, Yokohama-shi (JP); Chikayoshi Kamata, Kawasaki-shi (JP); Noriko Bota, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/834,255

(22) Filed: Jul. 12, 2010

(30) Foreign Application Priority Data
Aug. 11, 2009 (JP) 2009-186781

(51) Int. Cl. H01L 45/00; H01L 21/02

(52) U.S. Cl. 257/4; 438/382; 257/E21.004; 257/E45.001

(57) ABSTRACT

According to one embodiment, a resistance-change memory includes a laminated structure in which a lower electrode, an insulating film and an upper electrode are stacked, and a resistance-change film provided on a side surface of the laminated structure, and configured to store data in accordance with an electric resistance change.

### CROSS-REFERENCE TO RELATED APPLICATIONS

This application is based upon and claims the benefit of priority from Japanese Patent Application No. 2009-186781, filed Aug. 11, 2009; the entire contents of which are incorporated herein by reference.

### FIELD

Embodiments described herein relate generally to a resistance-change memory and a method of manufacturing the same.

### BACKGROUND

Nonvolatile semiconductor memories are widely used as storages of electronic devices such as a personal computer (PC), mobile telephone, digital camera and personal digital assistant (PDA). As a nonvolatile semiconductor memory of this kind, a phase-change random access memory (PCRAM), resistive random access memory (ReRAM) or magnetic random access memory (MRAM) that uses a variable resistance element as a memory cell has been developed.

The ReRAM uses, as memory information, the resistance value of the variable resistance element that changes in response to the application of a voltage or current. In the case of a binary operation, for example, “1” corresponds to a low-resistance state of the variable resistance element, and “0” corresponds to a high-resistance state of the variable resistance element. A change from the high-resistance state to the low-resistance state is called a set, and the opposite is called a reset. In this case, for example, a diode having a rectification function is connected to one end of the variable resistance element to avoid erroneous reading of the memory information.

In general, a laminated structure comprising the variable resistance element and the diode is collectively processed by, for example, a reactive ion etching (RIE) method after films necessary to form this laminated structure are stacked. A resistance-change film is etched by the RIE method during the processing, and its processed end face is subjected to an RIE atmosphere during the etching of other films. Therefore, the processed end face of the resistance-change film is damaged by the RIE process. Moreover, during the RIE process, reaction products adhere to the side surface of the laminated structure. Thus, the reaction products have to be removed by an asking treatment or wet etching treatment after the processing of the laminated structure. Here, there is concern that the end face of the resistance-change film might change in quality.

Furthermore, when the laminated structure is processed by the RIE method, the area of the element is substantially equal to the area of a mask layer used during the processing. That is, since the area of the resistance-change film is decided depending on a processed dimension, there is a limit to miniaturization. As an area of the resistance-change film becomes greater, a region where resistance of the resistance-change film can switch becomes greater. This may result in varied switching characteristics.

In general, there is a good possibility that the above-mentioned processing damage and property change of the film may deteriorate the switching characteristics of the resistance-change film and increase a leak current. When such a resistance-change film is used to configure a memory cell array, characteristic variation of the memory cells increases and there are more fail bits that show no switching operation.

As a related art of this kind, there has been disclosed a writing scheme for a resistance-change memory (see PCT National Publication No. WO2009/034687).

### BRIEF DESCRIPTION OF THE DRAWINGS

FIG. 1 is a plan view showing the configuration of a resistance-change memory according to a first embodiment;

FIG. 2 is a sectional view of the resistance-change memory along the line A-A′ indicated in FIG. 1;

FIG. 3 is a circuit diagram of the resistance-change memory;

FIG. 4 is a sectional view showing the process of manufacturing the resistance-change memory according to a first embodiment;

FIG. 5 is a plan view showing the resistance-change memory manufacturing process following FIG. 4;

FIG. 6 is a sectional view showing the process of manufacturing the resistance-change memory along the line A-A′ indicated in FIG. 5;

FIG. 7 is a sectional view showing the resistance-change memory manufacturing process following FIG. 6;

FIG. 8 is a sectional view showing the resistance-change memory manufacturing process following FIG. 7;

FIG. 9 is a sectional view showing the resistance-change memory manufacturing process following FIG. 8;

FIG. 10 is a sectional view showing the resistance-change memory manufacturing process following FIG. 9;

FIG. 11 is a plan view showing the configuration of a resistance-change memory according to a second embodiment;

FIG. 12 is a sectional view of the resistance-change memory along the line A-A′ indicated in FIG. 11;

FIG. 13 is a sectional view of the resistance-change memory along the line B-B′ indicated in FIG. 11;

FIG. 14 is a plan view showing the process of manufacturing the resistance-change memory according to the second embodiment;

FIG. 15 is a sectional view showing the process of manufacturing the resistance-change memory along the line A-A′ indicated in FIG. 14;

FIG. 16 is a sectional view showing the resistance-change memory manufacturing process following FIG. 15;

FIG. 17 is a sectional view showing the resistance-change memory manufacturing process following FIG. 16;

FIG. 18 is a plan view showing the resistance-change memory manufacturing process following FIG. 17;

FIG. 19 is a sectional view showing the process of manufacturing the resistance-change memory along the line B-B′ indicated in FIG. 18;

FIG. 20 is a sectional view showing the resistance-change memory manufacturing process following FIG. 19;

FIG. 21 is a sectional view showing the resistance-change memory manufacturing process following FIG. 20;

FIG. 22 is a sectional view showing the resistance-change memory manufacturing process following FIG. 21;

FIG. 23 is a plan view showing the configuration of a resistance-change memory according to a third embodiment;

FIG. 24 is a sectional view of the resistance-change memory along the line A-A′ indicated in FIG. 23;

FIG. 25 is a sectional view showing the process of manufacturing a resistance-change memory according to a fourth embodiment;

FIG. 26 is a sectional view showing the resistance-change memory manufacturing process following FIG. 25;

FIG. 27 is a sectional view showing the resistance-change memory manufacturing process following FIG. 26;

FIG. 28 is a sectional view showing the resistance-change memory manufacturing process following FIG. 27;

FIG. 29 is a sectional view showing the process of manufacturing a resistance-change memory according to a fifth embodiment;

FIG. 30 is a sectional view showing the resistance-change memory manufacturing process following FIG. 29;

FIG. 31 is a sectional view showing the resistance-change memory manufacturing process following FIG. 30;

FIG. 32 is a sectional view showing the resistance-change memory manufacturing process following FIG. 31;

FIG. 33 is a sectional view showing the process of manufacturing a resistance-change memory according to a sixth embodiment;

FIG. 34 is a sectional view showing the resistance-change memory manufacturing process following FIG. 33;

FIG. 35 is a sectional view showing the resistance-change memory manufacturing process following FIG. 34;

FIG. 36 is a sectional view showing the resistance-change memory manufacturing process following FIG. 35; and

FIG. 37 is a sectional view showing the resistance-change memory manufacturing process following FIG. 36.

### DETAILED DESCRIPTION

In general, according to one embodiment, there is provided a resistance-change memory comprising: a laminated structure in which a lower electrode, an insulating film and an upper electrode are stacked; and a resistance-change film provided on a side surface of the laminated structure, and configured to store data in accordance with an electric resistance change.

The embodiments will be described hereinafter with reference to the accompanying drawings. In the description which follows, the same or functionally equivalent elements are denoted by the same reference numerals, to thereby simplify the description.

### First Embodiment

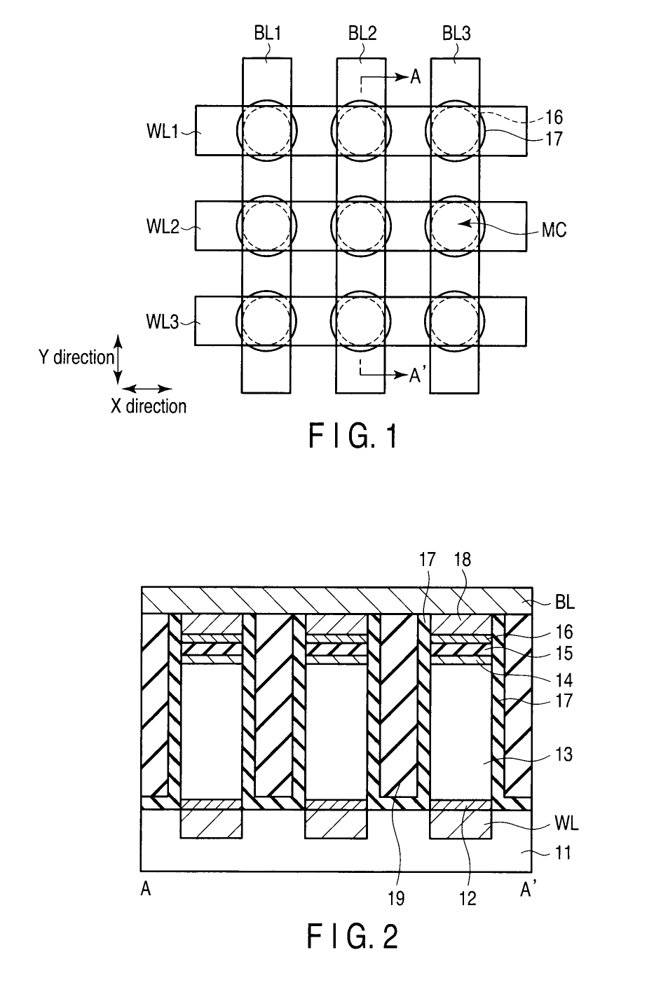

FIG. 1 is a plan view showing the configuration of a resistance-change memory according to a first embodiment. FIG. 2 is a sectional view of the resistance-change memory along the line A-A′ indicated in FIG. 1. The resistance-change memory according to this embodiment is a semiconductor storage device that uses a variable resistance element as a memory cell.

An interlayer insulating layer 11 made of, for example, silicon oxide (SiO₂) is provided on a given level layer which is formed on, for example, a silicon monocrystalline substrate (not shown). A plurality of lower wiring layers are provided in the interlayer insulating layer 11 to extend in an X direction. The lower wiring layers correspond to word lines WL. Although three word lines WL1 to WL3 are only shown in FIG. 1 by way of example, more word lines WL are actually arranged.

A plurality of upper wiring layers are provided above the word lines WL to extend in a Y direction that intersects with the X direction. The upper wiring layers correspond to bit lines BL. Although three bit lines BL1 to BL3 are only shown in FIG. 1 by way of example, more bit lines BL are actually arranged.

A plurality of memory cells MC are provided at the intersections of the word lines WL and the bit lines BL. That is, the resistance-change memory according to this embodiment is a cross-point type resistance-change memory.

The planar shape of the memory cell MC is not particularly limited. In this embodiment, the planar shape of the memory cell MC is, for example, circular. The memory cell MC is shaped like a pillar on the word line WL. The memory cell MC comprises a variable resistance element VR as a memory element, and a diode 13 as a selection element connected in series with the variable resistance element VR.

Specifically, a barrier film 12 is provided on the word line WL to prevent the metal of the word line WL from reacting with silicon (Si) of the diode 13. For example, tungsten (W) or aluminum (Al) is used for the word line WL. For example, titanium nitride (TiN) or a laminated film of titanium (Ti) and titanium nitride (TiN) is used for the barrier film 12. The diode 13 is provided on the barrier film 12. For example, a PIN diode is used as the diode 13. The PIN diode comprises an N-type semiconductor layer, a P-type semiconductor layer, and an intrinsic semiconductor layer (I layer) sandwiched between the former layers.

A lower electrode 14, an insulating film 15 and an upper electrode 16 are stacked on the diode 13 in this order. The insulating film 15 is made of a stable material the resistivity of which does not change when supplied with a voltage or current. A conductive stopper layer 18 is provided on the upper electrode 16. The stopper layer 18 functions as a stopper during a chemical mechanical polishing (CMP) process. For example, tungsten (W) is used for the stopper layer 18.

Here, a resistance-change film 17 according to this embodiment is not formed between the lower electrode 14 and the upper electrode 16, but is provided on the side surface of the laminated film comprising at least the lower electrode 14, the insulating film 15 and the upper electrode 16. Specifically, the resistance-change film 17 is provided on and around the circumferential surface of the pillar-shaped laminated structure comprising the barrier film 12, the diode 13, the lower electrode 14, the insulating film 15, the upper electrode 16 and the stopper layer 18. That is, the resistance-change film 17 is formed as a sidewall covering the circumferential surface of the laminated structure. Due to the presence of this resistance-change film 17, a current path through the lower electrode 14, the resistance-change film 17 and the upper electrode 16 is formed. Thus, the lower electrode 14, the resistance-change film 17 and the upper electrode 16 constitute the variable resistance element VR.

The thickness of the resistance-change film 17 is set at less than half the distance between adjacent laminated films (comprising, in particular, the lower electrode 14, the insulating film 15 and the upper electrode 16). In this embodiment, each of the word lines WL and bit lines BL is processed at a minimum feature size (minimum processing size) F. Therefore, the width of each of the word lines WL and bit lines BL is F, and the distance between adjacent lines is also F. In this case, the diameter of the processed laminated film is also F, and the distance between adjacent laminated films is also set at F. Accordingly, the thickness of the resistance-change film 17 is set at less than F/2. When these conditions are satisfied, contact of the side surface of the resistance-change film 17 between adjacent memory cells MC can be prevented.

When supplied with a voltage or current, the resistance-change film 17 can take at least two resistance values at room temperature as bistable states. The two stable resistance values can be written or read to enable at least binary memory operation. In order for the variable resistance element VR to perform the binary memory operation, for example, the low-resistance state of the resistance-change film 17 is set to correspond to “1”, and its high-resistance state is set to correspond to “0”. A change from the high-resistance state to the low-resistance state is called a set, and the opposite is called a reset.

For a stable change of the resistance state of the resistance-change film 17, the resistance-change film 17 needs to have a lower dielectric breakdown resistance (dielectric breakdown voltage) than the insulating film 15 provided between the lower electrode 14 and the upper electrode 16. In general, a material having a wider bandgap has a higher dielectric breakdown resistance. Therefore, silicon oxide (SiO₂), aluminum oxide (AlOₓ), hafnium oxide (HfOₓ), zirconium oxide (ZrOₓ) or tantalum oxide (TaOₓ) is desirable as the material for the insulating film 15. “x” indicating a composition ratio is a natural number equal to or more than 1.

A desirable material is decided for the resistance-change film 17 depending on the material for the insulating film 15.

(1) When the insulating film 15 is made of SiO₂, a desirable material for the resistance-change film 17 is AlOₓ, HfOₓ, NiOₓ, CoOₓ, TiOₓ, NbOₓ, TaOₓ, ZrOₓ, MnOₓ, CrOₓ, FeOₓ or CuOₓ.

(2) When the insulating film 15 is made of AlOₓ, a desirable material for the resistance-change film 17 is HfOₓ, NiOₓ, CoOₓ, TiOₓ, NbOₓ, TaOₓ, ZrOₓ, MnOₓ, CrOₓ, FeOₓ or CuOₓ.

(3) When the insulating film 15 is made of HfOₓ or ZrOₓ, a desirable material for the resistance-change film 17 is NiOₓ, CoOₓ, TiOₓ, NbOₓ, TaOₓ, MnOₓ, CrOₓ, FeOₓ or CuOₓ.

(4) When the insulating film 15 is made of TaOₓ, a desirable material for the resistance-change film 17 is NiOₓ, CoOₓ, TiOₓ, NbOₓ, MnOₓ, CrOₓ, FeOₓ or CuOₓ.

If the materials are selected for the insulating film 15 and the resistance-change film 17 as described above, a current path (filament) is formed in the resistance-change film 17 without any dielectric breakdown in the insulating film 15. When the variable resistance element VR is in the low-resistance state, a current passes across the lower electrode 14 and the upper electrode 16 through the filament.

The material for the lower electrode 14 and the upper electrode 16 may be, for example, titanium nitride (TiN), tungsten nitride (WN), tantalum nitride (TaN) or niobium nitride (NbN).

The bit line BL extending in the Y direction is provided on the stopper layer 18. For example, tungsten (W) or aluminum (Al) is used for the bit line BL. An interlayer insulating layer 19 made of, for example, silicon oxide (SiO₂) is provided between the memory cells MC. Thus, the resistance-change memory according to the first embodiment is configured.

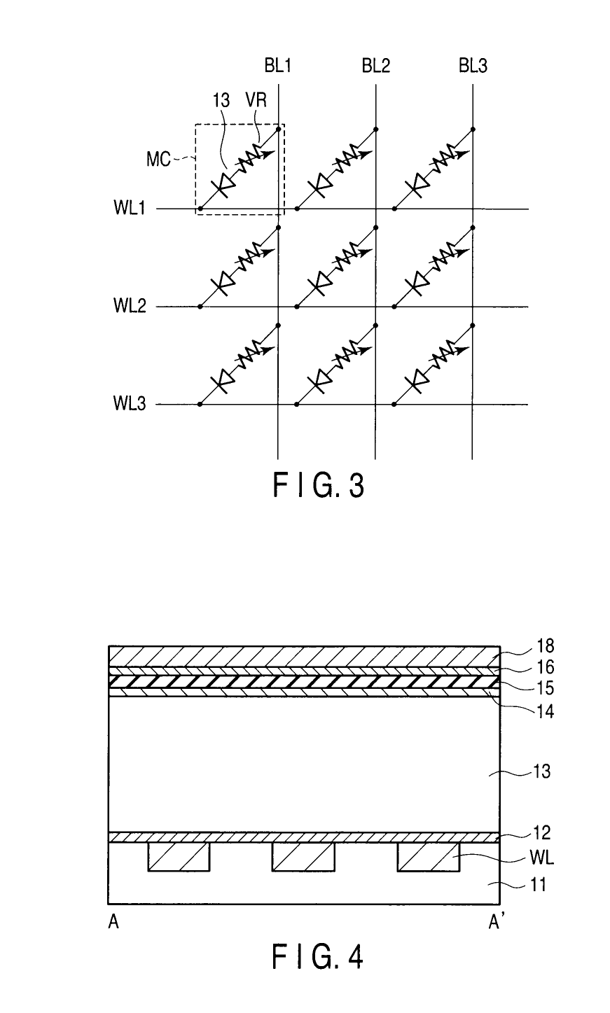

FIG. 3 is a circuit diagram of the resistance-change memory. The memory cells MC are disposed at the intersections of the word lines WL and the bit lines BL. The memory cell MC comprises the variable resistance element VR and the diode 13 that are connected in series. One end of the variable resistance element VR is connected to the bit line BL. The other end of the variable resistance element VR is connected to the anode of the diode 13. The cathode of the diode 13 is connected to the word line WL. The connection of the diode 13 is not exclusively as shown in FIG. 3 and is properly set depending on the configuration of circuits around the resistance-change memory and the configuration of the resistance-change film 17.

(Manufacturing Method)

Now, a method of manufacturing the resistance-change memory according to the first embodiment is described by way of example with reference to the drawings. It is to be noted that sectional views of the manufacturing process used in the following explanation show the same part along the line A-A′ indicated in FIG. 1.

As shown in FIG. 4, a plurality of lower wiring layers (word lines WL) are formed in an interlayer insulating layer 11 by, for example, a damascene method. That is, a plurality of grooves in the same shape as the word lines WL are formed in the interlayer insulating layer 11. After a wiring material is deposited in the grooves, the upper surface of the interlayer insulating layer 11 is planarized so that the wiring material may only remain in the grooves. Thus, a plurality of linear word lines WL extending in the X direction are formed in the interlayer insulating layer 11.

Then, a barrier film 12, materials (a P-type semiconductor layer, an intrinsic semiconductor layer and an N-type semiconductor layer) for a PIN diode 13, a lower electrode 14, an insulating film 15, an upper electrode 16 and a stopper layer 18 are stacked on the word lines WL and the interlayer insulating layer 11 in this order. For the diode 13, a source gas containing phosphorus (P) and boron (B) is selectively supplied during the formation of a silicon layer, thereby forming the P-type semiconductor layer, the intrinsic semiconductor layer containing no impurity (or having a sufficiently low impurity concentration) and the N-type semiconductor layer. Otherwise, the PIN diode 13 may be formed by ion implantation after the silicon layer is formed.

For example, a laminated film of titanium silicide and titanium nitride (TiN) is used as the lower electrode 14. That is, titanium (Ti) is provided between titanium nitride (TiN) and silicon (Si), and titanium (Ti) is silicided to form titanium silicide at the interface between the diode 13 and titanium nitride (TiN). Interface resistance can be reduced by providing titanium silicide at the interface between the diode 13 and titanium nitride (TiN). For example, titanium nitride (TiN) is used for the upper electrode 16.

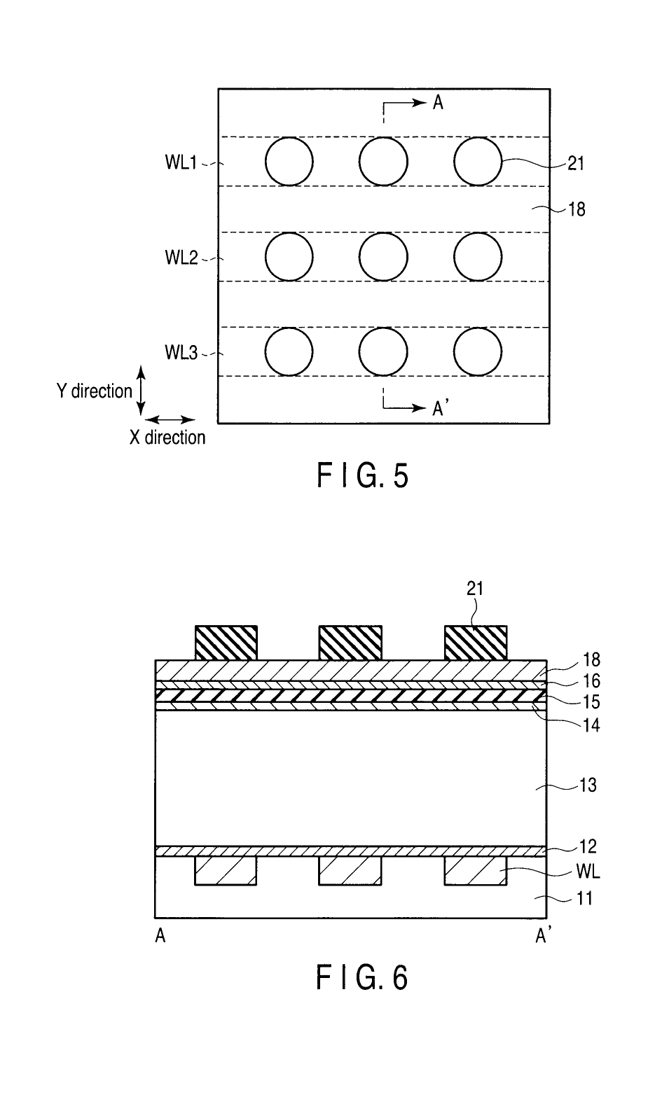

Then, as shown in FIG. 5 (plan view) and FIG. 6 (sectional view), hard mask layers 21 corresponding to the number of memory cells MC are formed by lithography and an RIE method on the stopper layer 18 and in regions where the memory cells MC are to be formed. The planar shape of each of the hard mask layers 21 is the same as the final planar shape of the upper electrode 16. For example, silicon oxide, silicon oxynitride or silicon nitride is used for the hard mask layer 21.

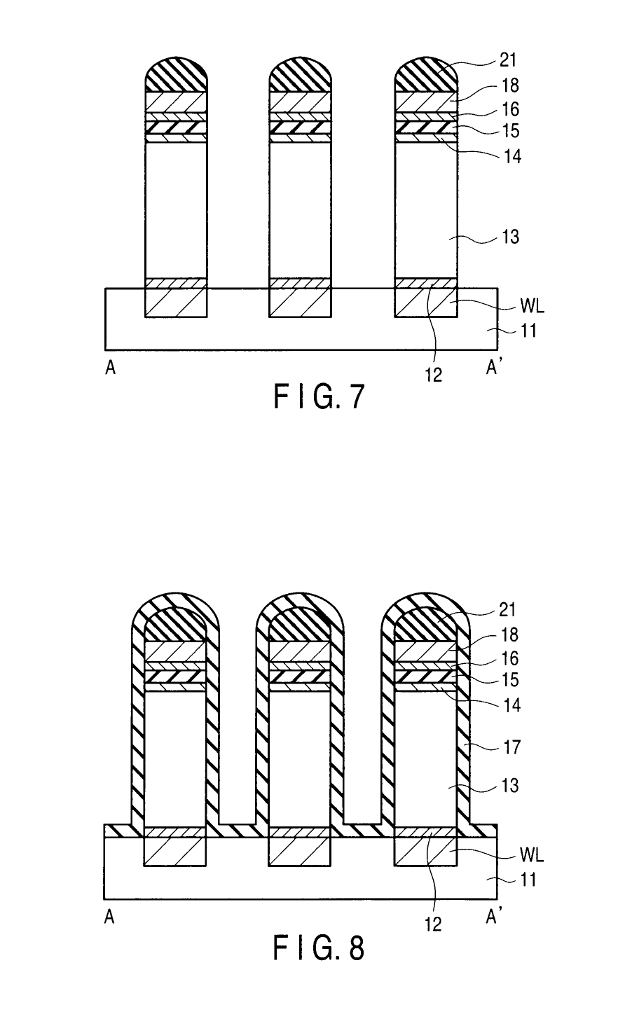

Then, as shown in FIG. 7, using the hard mask layer 21 as a mask, the laminated structure comprising the barrier film 12, the diode 13, the lower electrode 14, the insulating film 15, the upper electrode 16 and the stopper layer 18 is processed into a pillar shape by, for example, the RIE method. Here, reaction products resulting from the RIE process adhere to the side surface of the laminated structure. Therefore, the reaction products adhering to the side surface of the laminated structure are removed by an ashing treatment or wet etching treatment.

Then, as shown in FIG. 8, a resistance-change film 17 is deposited on the entire surface of the device by, for example, an atomic layer deposition (ALD) method or a chemical vapor deposition (CVD) method. As a result, the resistance-change film 17 is formed on and around the circumferential surface of the pillar-shaped laminated structure. The pillar-shaped memory cell MC comprising the variable resistance element VR and the diode 13 is formed by the process of FIG. 8. In this embodiment, the resistance-change film 17 is also formed on the interlayer insulating layer 11. Thus, the resistance-change film 17 is continuous between adjacent laminated structures.

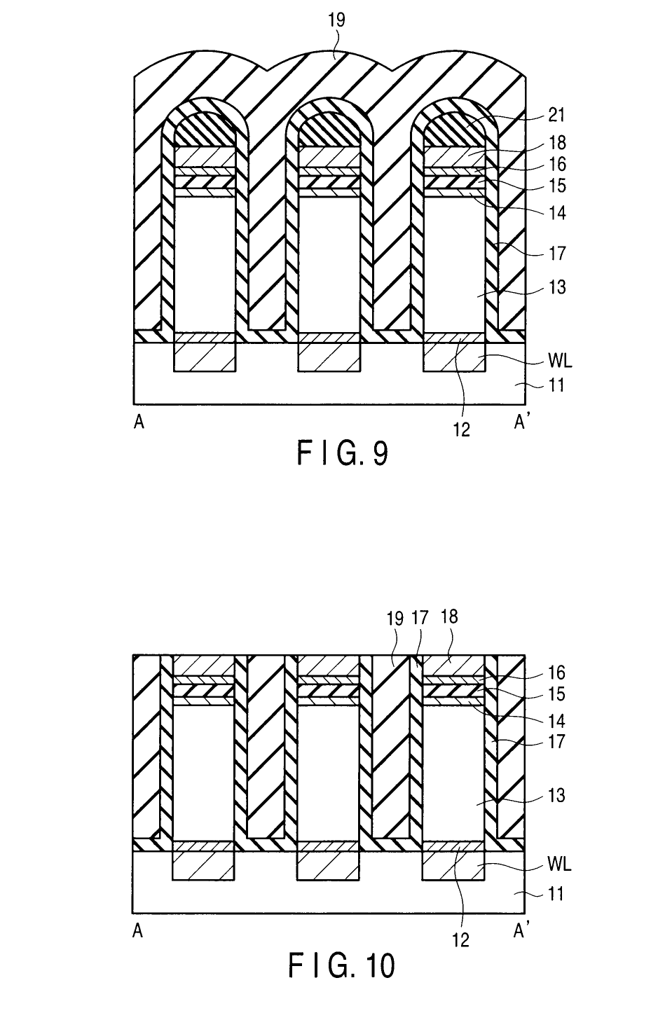

Then, as shown in FIG. 9, an interlayer insulating layer 19 is deposited on the entire surface of the device by, for example, the CVD method to fill the space between the memory cells MC. Then, as shown in FIG. 10, using the stopper layer 18 as a CMP stopper, the hard mask layer 21 is chipped off by the chemical mechanical polishing (CMP) method, thereby exposing the upper surface of the stopper layer 18. Thus, the upper surface of the memory cell MC and the upper surface of the interlayer insulating layer 19 are planarized. At the same time, the resistance-change film 17 formed on the hard mask layer 21 is also removed. Then, contacts for peripheral circuits are formed on the outside of a memory cell array. In this case, the resistance-change film 17 remaining around the memory cell array can be used as an etching stopper during the RIE process.

Then, as shown in FIG. 2, a material for upper wiring layers (bit lines BL) is deposited on the memory cells MC and the interlayer insulating layer 19. Then, the bit lines BL are processed into a linear shape by lithography and by the RIE method. In this way, the resistance-change memory according to the first embodiment is manufactured.

(Advantages)

As has been described above in detail, in the cross-point type resistance-change memory according to the first embodiment in which the memory cell MC is disposed at the intersection of the word line WL and the bit line BL, the variable resistance element VR is provided on the selection element (e.g., diode) 13 included in the memory cell MC. This variable resistance element VR comprises a laminated film including the lower electrode 14, the insulating film 15 and the upper electrode 16, and the resistance-change film 17 formed on the side surface of the laminated film.

Thus, according to the first embodiment, the resistance-change film 17 is not subjected to the etching process for processing the laminated film including the lower electrode 14, the insulating film 15 and the upper electrode 16 as well as the diode 13 into a pillar shape. This makes it possible to reduce the processing damage of the resistance-change film 17. Moreover, the resistance-change film 17 is not subjected to the process of removing the reaction products formed on the laminated film and on the side surface of the diode 13. This makes it possible to reduce quality deterioration of the resistance-change film 17. As a result, deterioration of the switching characteristics can be reduced when the resistance-change film 17 changes from the high-resistance state to the low-resistance state or from the low-resistance state to the high-resistance state. Moreover, a leak current from the resistance-change film 17 can be reduced.

Furthermore, the filament formed in the resistance-change film 17 when the resistance-change film 17 changes to the low-resistance state extends in a longitudinal direction. Thus, a region where the filament is formed, that is, resistance of the resistance-change film 17 can switch is determined by the thickness of the resistance-change film 17. The thickness of the resistance-change film 17 is not dependent on the feature size at which the upper electrode 16 and the diode 13 are processed. Therefore, the switchable region of the resistance-change film 17 can be reduced by reducing the thickness of the resistance-change film 17. Consequently, variation of the switching characteristics of the resistance-change film 17 can be reduced.

### Second Embodiment

In a second embodiment, a resistance-change memory is manufactured by a method different from the method used in the first embodiment. Due the difference of the manufacturing method, the structure of the resistance-change memory according to the second embodiment is different from that of the resistance-change memory according to the first embodiment.

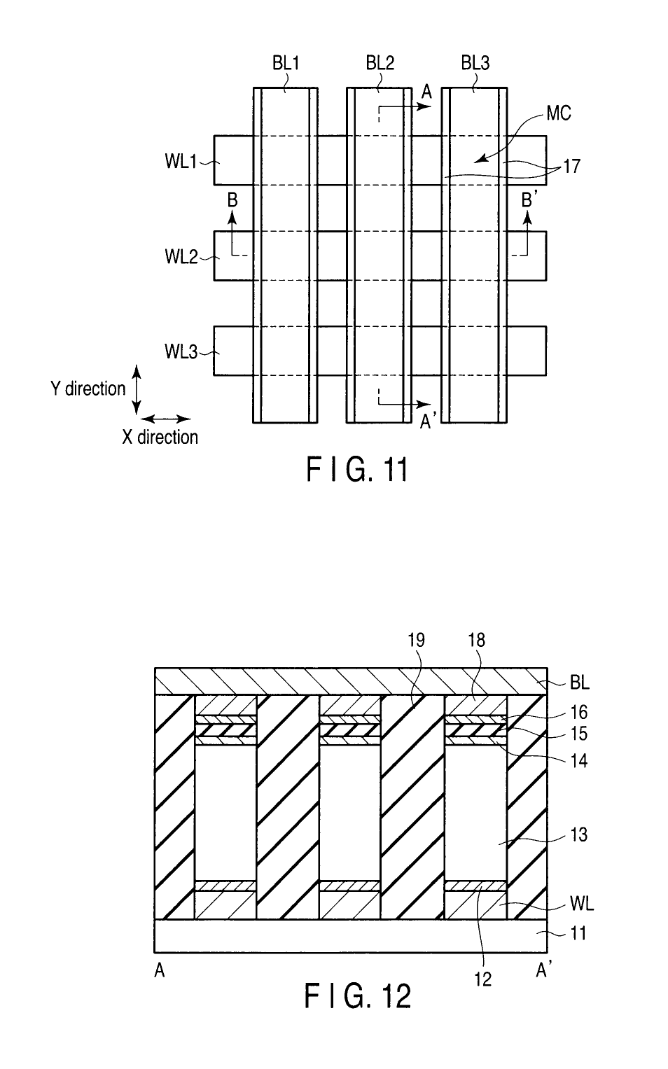

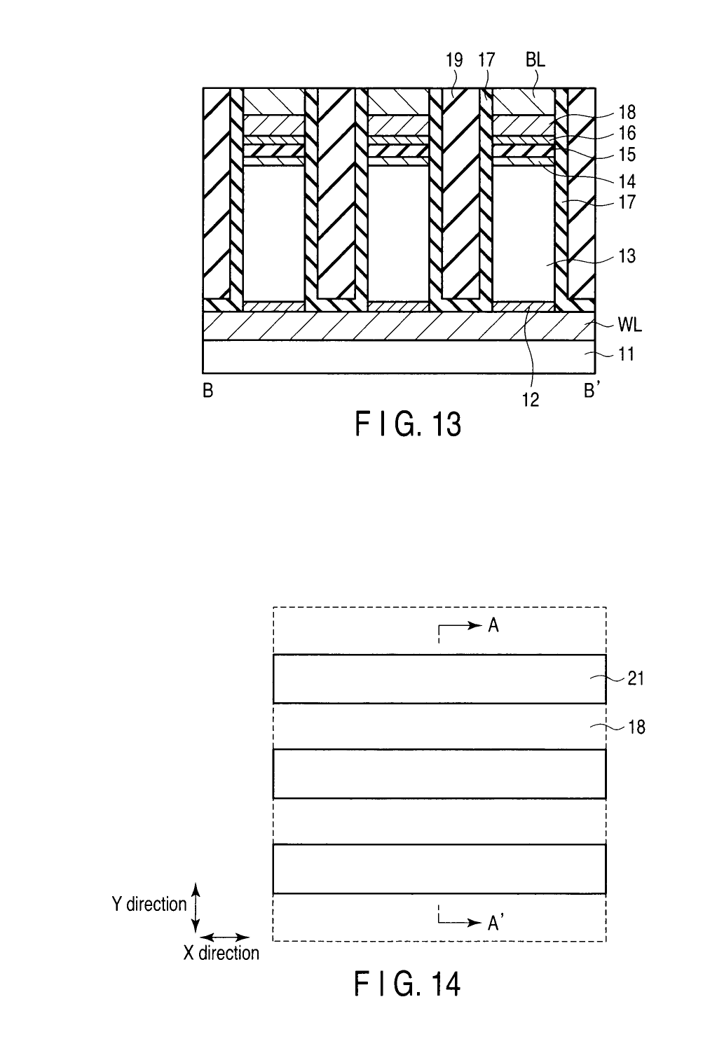

FIG. 11 is a plan view showing the configuration of the resistance-change memory according to the second embodiment. FIG. 12 is a sectional view of the resistance-change memory along the line A-A′ indicated in FIG. 11. FIG. 13 is a sectional view of the resistance-change memory along the line B-B′ indicated in FIG. 11.

The planar shape of a memory cell MC according to the second embodiment is quadrangular because of the manufacturing method described later. Resistance-change films 17 are provided on both of the side surfaces, in the X direction, of a laminated film which comprises at least a lower electrode 14, an insulating film 15 and an upper electrode 16. Specifically, the resistance-change films 17 are provided on both of the side surfaces, in the X direction, of the pillar-shaped laminated structure comprising a barrier film 12, a diode 13, the lower electrode 14, the insulating film 15, the upper electrode 16 and a stopper layer 18. In addition, the resistance-change film 17 is not provided on both of the side surfaces of the laminated structure in the Y direction. The configuration according to this embodiment is the same as that according to the first embodiment in other respects.

The thickness of the resistance-change film 17 is set at less than half the distance between the laminated films (comprising the lower electrode 14, the insulating film 15 and the upper electrode 16) adjacent in the X direction. In this embodiment, each of word lines WL and bit lines BL is processed at the minimum feature size F. Therefore, the width of each of the word lines WL and bit lines BL is F, and the distance between adjacent lines is also F. In this case, the length of the laminated film in the X direction is the same as the width of the bit line BL, and the length of the laminated film in the Y direction is the same as the width of the word line WL. Further, the distance between the laminated films adjacent in the X direction as well as the distance between the laminated films adjacent in the Y direction is set at F. Accordingly, the thickness of the resistance-change film 17 is set at less than F/2. When these conditions are satisfied, contact of the side surface of the resistance-change film 17 between adjacent memory cells MC can be prevented.

(Manufacturing Method)

Now, a method of manufacturing the resistance-change memory according to the second embodiment is described by way of example with reference to the drawings.

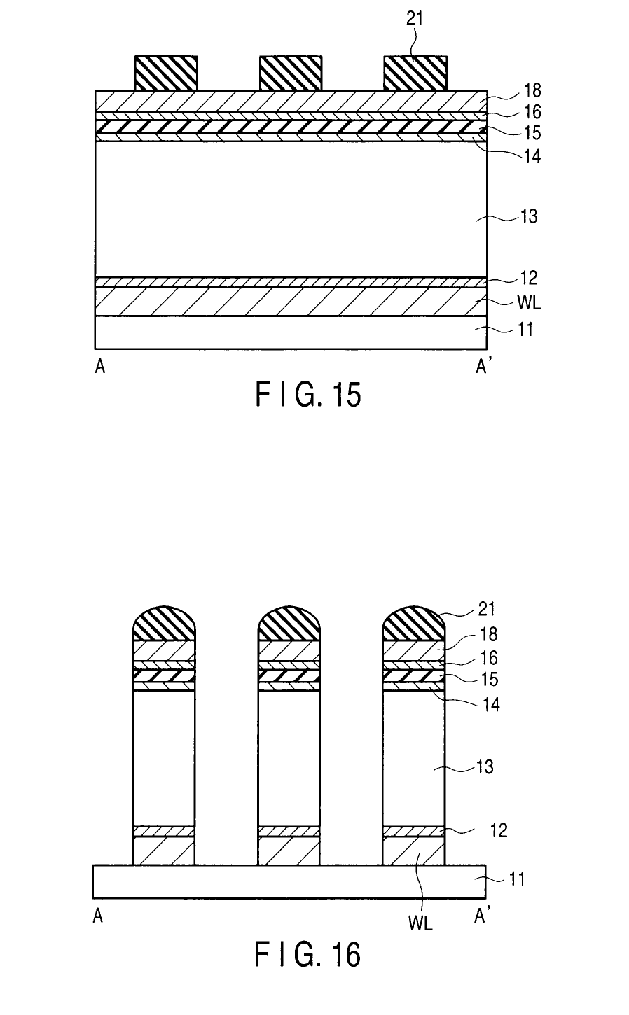

As shown in FIG. 14 (plan view) and FIG. 15 (sectional view), a material for a word line WL, a barrier film 12, materials (a P-type semiconductor layer, an intrinsic semiconductor layer and an N-type semiconductor layer) for a PIN diode 13, a lower electrode 14, an insulating film 15, an upper electrode 16 and a stopper layer 18 are stacked on an interlayer insulating layer 11 in this order. Then, linear hard mask layers 21 each having the same planar shape as the final planar shape of the word line WL are formed on the stopper layer 18 by lithography and by the RIE method.

Then, as shown in FIG. 16, using the hard mask layers 21 as a mask, the laminated structure comprising the word line WL, the barrier film 12, the diode 13, the lower electrode 14, the insulating film 15, the upper electrode 16 and the stopper layer 18 is processed into a linear shape by, for example, the RIE method. The fabrication of the word lines WL is completed by this process. Here, reaction products resulting from the RIE process adhere to the side surface of the laminated structure. Therefore, the reaction products adhering to the side surface of the laminated structure are removed by an ashing treatment or wet etching treatment.

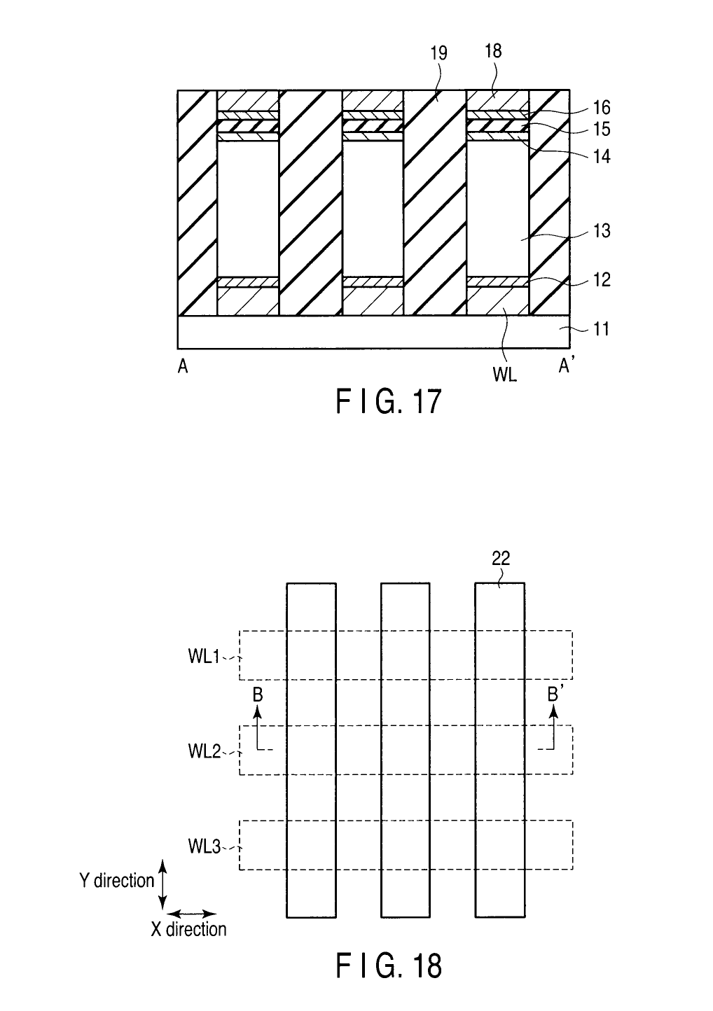

Then, as shown in FIG. 17, an interlayer insulating layer 19 is deposited on the entire surface of the device by, for example, the CVD method to fill the space between the linear laminated structures. Then, using the stopper layer 18 as a CMP stopper, the hard mask layers 21 are chipped off by the CMP method, thereby exposing the upper surface of the stopper layer 18. Thus, the upper surface of the interlayer insulating layer 19 is planarized.

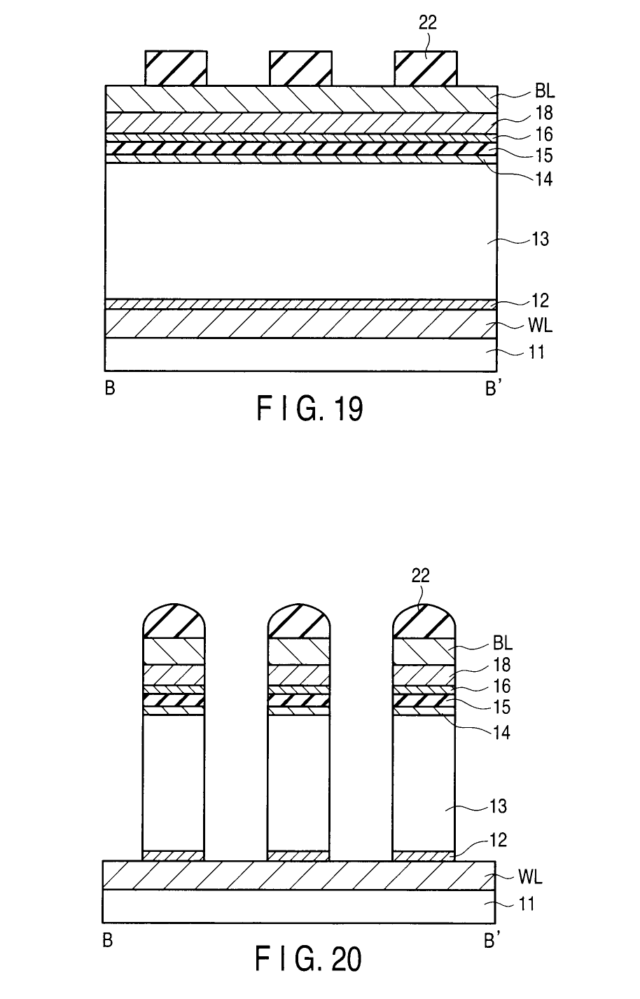

Then, as shown in FIG. 18 (plan view) and FIG. 19 (sectional view), a material for a bit line BL is deposited on the entire surface of the device. Then, linear hard mask layers 22 each having the same planar shape as the final planar shape of the bit line BL are formed on the material for the bit line BL. For example, silicon oxide, silicon oxynitride or silicon nitride is used for the hard mask layers 22.

Then, as shown in FIG. 20, using the hard mask layers 22 as a mask, the bit line BL, the stopper layer 18, the upper electrode 16, the insulating film 15, the lower electrode 14, the diode 13 and the barrier film 12 are etched by, for example, the RIE method, thereby partly exposing the upper surface of the word lines WL. By this process, the bit lines BL are processed into a linear shape. Moreover, the laminated structure comprising the barrier film 12, the diode 13, the lower electrode 14, the insulating film 15, the upper electrode 16 and the stopper layer 18 is processed into a pillar shape so that the planar shape of this laminated structure may be quadrangular. Here, reaction products resulting from the RIE process adhere to the side surface of the laminated structure. Therefore, the reaction products adhering to the side surface of the laminated structure are removed by an ashing treatment or wet etching treatment.

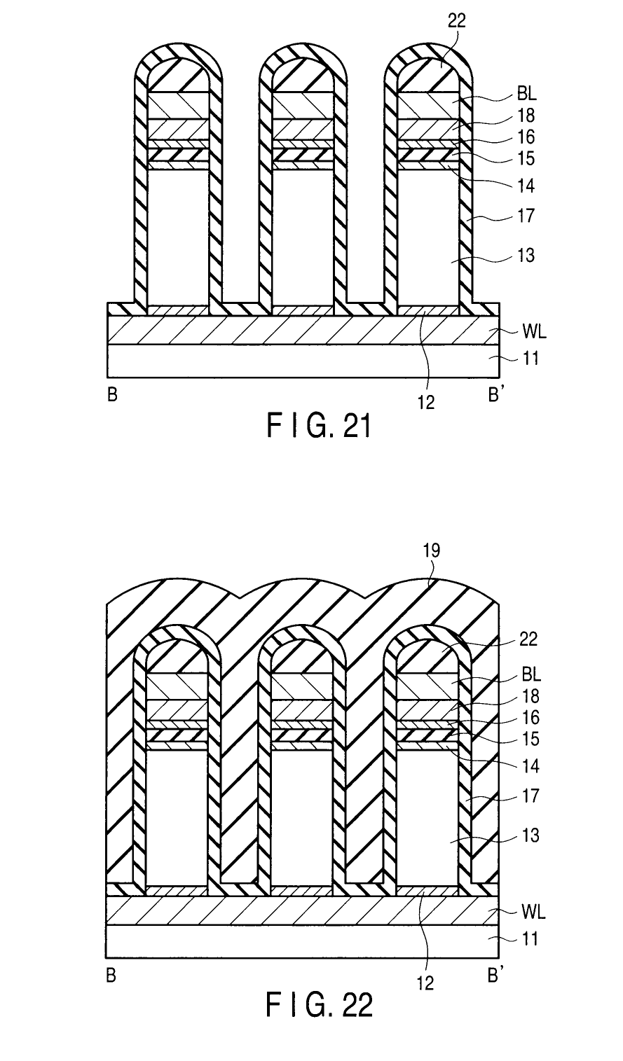

Then, as shown in FIG. 21, a resistance-change film 17 is deposited on the entire surface of the device by, for example, the ALD method or CVD method. As a result, the resistance-change film 17 is formed on both of the side surfaces of the pillar-shaped laminated structure in the X direction. A pillar-shaped memory cell MC comprising the variable resistance element VR and the diode 13 is formed by such the process of FIG. 21. In this embodiment, the resistance-change film 17 is also formed on the interlayer insulating layer 11. Thus, the resistance-change film 17 is continuous between the laminated structures adjacent in the X direction.

Then, as shown in FIG. 22, an interlayer insulating layer 19 is deposited on the entire surface of the device by, for example, the CVD method to fill the space between the linear laminated structures. Then, as shown in FIG. 13, using the bit lines BL as a CMP stopper, the hard masks layer 22 are chipped off by the CMP method, thereby exposing the upper surface of the bit lines BL. Thus, the upper surface of the interlayer insulating layer 19 is planarized. At the same time, the resistance-change films 17 formed on the hard mask layers 22 are also removed. Then, contacts for peripheral circuits are formed on the outside of a memory cell array. The resistance-change film 17 remaining around the memory cell array can be used as an etching stopper during the RIE process. In this way, the resistance-change memory according to the second embodiment is manufactured.

As has been described above in detail, the second embodiment also makes it possible to form the memory cell MC comprising the laminated film which includes the lower electrode 14, the insulating film 15 and the upper electrode 16 as well as the resistance-change films 17 provided on both of the side surfaces of the laminated film in the X direction. Thus, according to the second embodiment, a resistance-change memory having the same advantages as in the first embodiment can be obtained.

### Third Embodiment

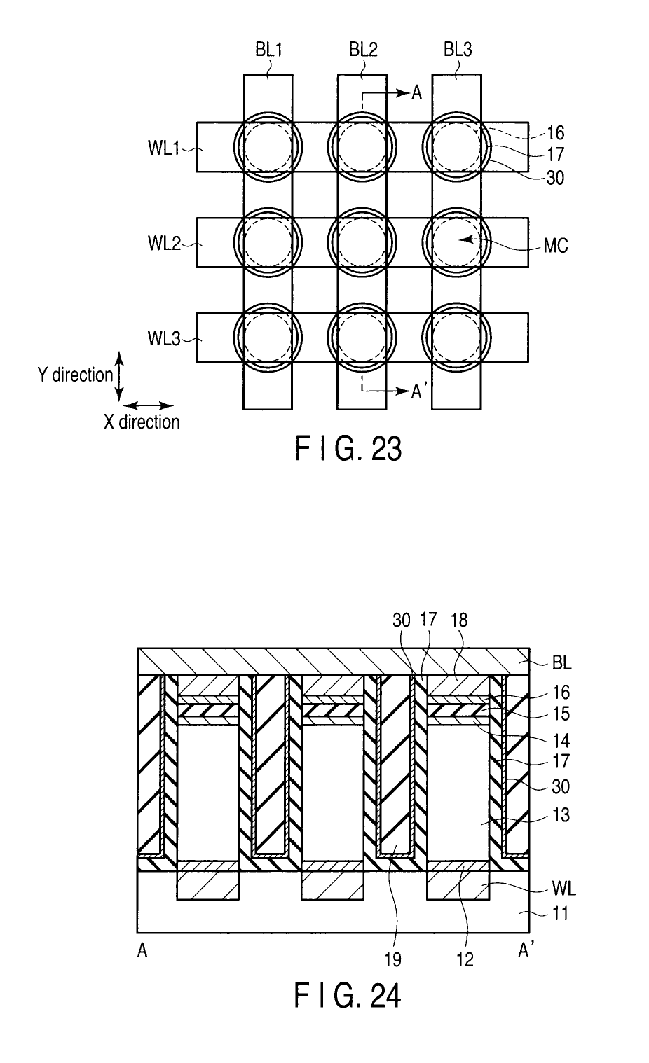

In a third embodiment, the crystallinity of a resistance-change film 17 is enhanced, and the crystalline orientation of the resistance-change film 17 is controlled, thereby improving the characteristics, in particular, switching characteristics of the resistance-change film 17. FIG. 23 is a plan view showing the configuration of a resistance-change memory according to the third embodiment. FIG. 24 is a sectional view of the resistance-change memory along the line A-A′ indicated in FIG. 23.

A crystallized or highly crystalline conductive material is used for at least one or desirably both of a lower electrode 14 and an upper electrode 16 according to the third embodiment. Such a conductive material may be, for example, tungsten (W) or titanium nitride (TiN). These materials can be crystallized by a heat treatment.

A crystallized or highly crystalline crystal film 30 is provided on and around the circumferential surface of the resistance-change film 17. For example, titanium nitride (TiN) is used for the crystal film 30.

In the resistance-change memory having such a configuration, the resistance-change film 17 in contact with the highly crystalline lower electrode 14 and upper electrode 16 has the same crystalline orientation as the lower electrode 14 and the upper electrode 16. The resistance-change film 17 is also in contact with the highly crystalline crystal film 30, and therefore has the same crystalline orientation as the crystal film 30. Thus, the crystals of the resistance-change film 17 are aligned, i.e., the crystallinity of the resistance-change film 17 is enhanced. This allows variation of the switching characteristics of the resistance-change film 17 to be reduced.

In addition, the crystals of the resistance-change film 17 are desirably oriented in the longitudinal direction, that is, has an in-plane orientation. This is enabled by controlling the crystalline orientation of the lower electrode 14, the upper electrode 16 or the crystal film 30. When these conditions are satisfied, the filament is aligned with the longitudinal direction. This allows switching characteristics of the resistance-change film 17 to be further improved.

In the process of manufacturing the lower electrode 14 and the upper electrode 16, another step is added to subject the lower electrode 14 and the upper electrode 16 to a heat treatment to crystallize these electrodes after the lower electrode 14 and the upper electrode 16 are formed. In the process of manufacturing the crystal film 30, the resistance-change film 17 is formed before the crystal film 30 is formed. Further, another step is added to subject the crystal film 30 to a heat treatment to crystallize this film.

In the above explanation, in order to align the crystal of the resistance-change film 17, two methods are used, namely, a method that uses the highly crystalline lower electrode 14 and upper electrode 16, and a method that uses the highly crystalline crystal film 30. However, one of these methods may be only used.

### Fourth Embodiment

The resistance-change film 17 may be difficult to chip off by the CMP process, depending on the material used therefor. Thus, in a fourth embodiment, after a resistance-change film 17 is formed, the resistance-change film 17 is partly etched by, for example, the RIE method, that is, the sidewall of the resistance-change film 17 is processed to remove the resistance-change film 17 formed on a hard mask layer 21. This enables easy removal of the hard mask layer 21 in the CMP process.

A method of manufacturing a resistance-change memory according to the fourth embodiment is described below by way of example with reference to the drawings. It is to be noted that the manufacturing process is the same as that in the first embodiment up to the formation of the resistance-change film 17.

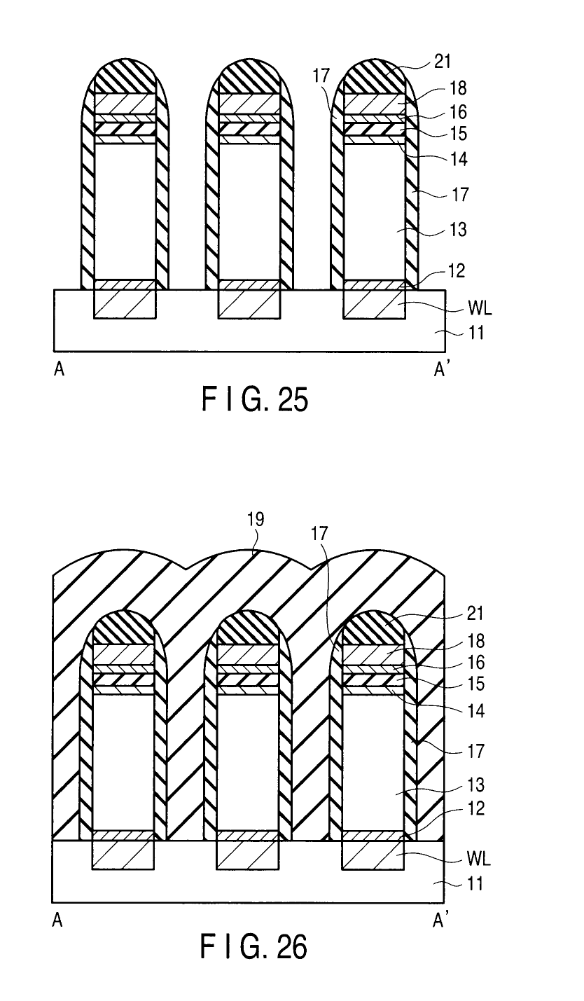

As shown in FIG. 25, the resistance-change film 17 is partly etched by, for example, the RIE method, thereby removing the resistance-change film 17 formed on the hard mask layer 21. At the same time, the resistance-change film 17 formed on an interlayer insulating layer 11 is also removed.

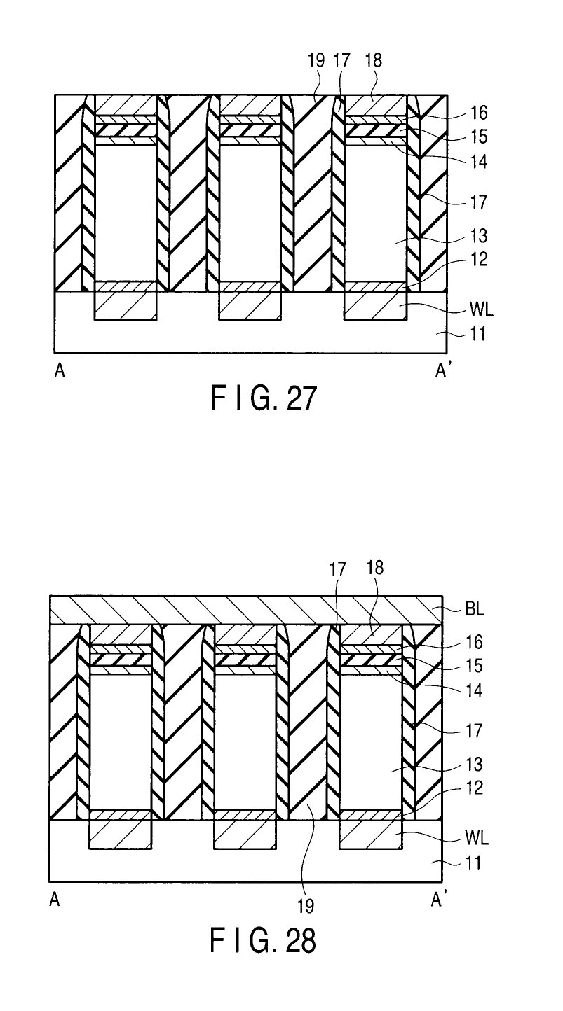

Then, as shown in FIG. 26, an interlayer insulating layer 19 is deposited on the entire surface of the device by, for example, the CVD method to fill the space between memory cells MC. Then, as shown in FIG. 27, using stopper layers 18 as a CMP stopper, the hard mask layers 21 are chipped off by the CMP method, thereby exposing the upper surfaces of the stopper layers 18. Here, since the resistance-change film 17 is not formed on the hard mask layer 21, a planarization process using the CMP method can be easily carried out. As a result, the upper surface of the memory cell MC and the upper surface of the interlayer insulating layer 19 are planarized.

Then, as shown in FIG. 28, a material for upper wiring layers (bit lines BL) is deposited on the memory cells MC and the interlayer insulating layer 19. Then, the bit lines BL are processed into a linear shape by lithography and the RIE method. In this way, the resistance-change memory according to the fourth embodiment is manufactured.

As has been described above in detail, according to the fourth embodiment, planarity of the memory cell MC and the interlayer insulating layer 19 can be maintained even when the resistance-change film 17 is provided on the circumferential surface of a laminated film comprising a lower electrode 14, an insulating film 15 and an upper electrode 16. Thus, memory cell arrays can be laminated in the longitudinal direction.

### Fifth Embodiment

In a fifth embodiment, a resistance-change film 17 is partly provided on the side surface of a pillar configuring a memory cell MC in such a manner as to cover the pillar from its upper portion to middle portion. Further, a void is formed between the memory cells MC to inhibit thermal and electrical interference between adjacent memory cells MC.

A method of manufacturing a resistance-change memory according to the fifth embodiment is described below by way of example with reference to the drawings. It is to be noted that the manufacturing process is the same as that in the first embodiment up to processing of a laminated structure into a pillar shape.

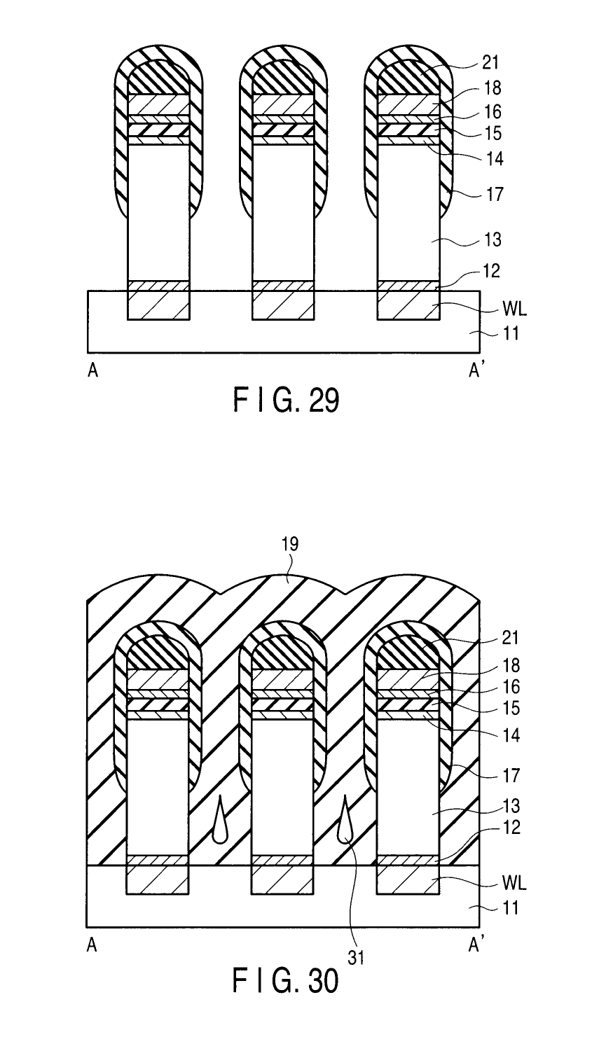

As shown in FIG. 29, the resistance-change film 17 is formed by a manufacturing process that provides a low coverage. Thus, the resistance-change film 17 covering the pillar from its upper portion to middle portion is formed. That is, since the resistance-change film 17 is not formed on the lower portion of the pillar, the distance between the upper portions of the pillars is smaller than the distance between the lower portions thereof.

Then, as shown in FIG. 30, an interlayer insulating layer 19 is deposited on the entire surface of the device by, for example, the CVD method to fill the space between pillars. At the same time, a void 31 is formed in the interlayer insulating layer 19 between the lower portions of the pillars because the distance between the upper portions of the pillars is different from the distance between the lower portions of the pillars.

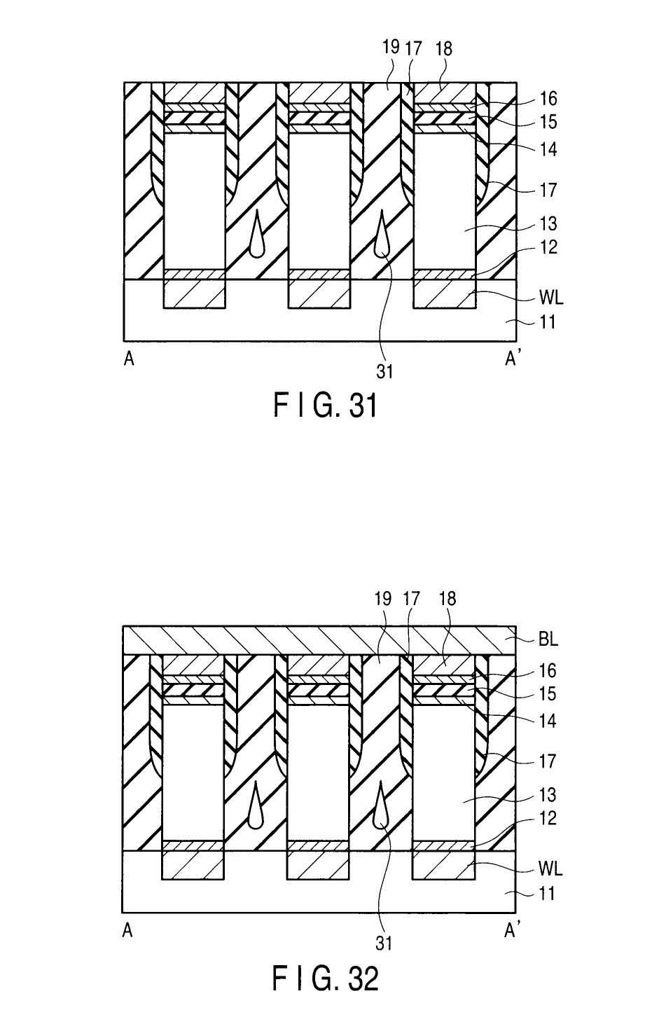

Then, as shown in FIG. 31, using stopper layers 18 as a CMP stopper, the hard mask layers 21 are chipped off by the CMP method, thereby exposing the upper surfaces of the stopper layers 18. Thus, the upper surfaces of the memory cells MC and the upper surface of the interlayer insulating layer 19 are planarized.

Then, as shown in FIG. 32, a material for upper wiring layers (bit lines BL) is deposited on the memory cells MC and the interlayer insulating layer 19. Then, the bit lines BL are processed into a linear shape by lithography and by the RIE method. In this way, the resistance-change memory according to the fifth embodiment is manufactured.

In general, the resistance-change film 17 has a high dielectric constant in many cases. However, when the highly dielectric film is present between the memory cells MC, electric field coupling is intensified, leading to a high capacitance between the memory cells MC. This coupling capacitance may cause the adjacent cells to malfunction. However, according to this embodiment, the highly dielectric film is broken on the lower portions of the pillars, that is, the highly dielectric film is not formed as a continuous film. Thus, the electric field coupling can be suppressed. This inhibits the memory cells MC from malfunctioning.

Furthermore, the void 31 is formed between the memory cells MC. The void 31 is highly insulative and can therefore inhibit the thermal and electrical interference of the memory cells MC. As a result, a resistance-change memory with reduced failure and malfunctioning can be configured even when the density of the memory cells is high.

### Sixth Embodiment

In a sixth embodiment, a laminated film comprising a lower electrode 14, an insulating film 15 and an upper electrode 16 is tapered. This ensures that a resistance-change film 17 can be formed on the side surface of the laminated film even when the resistance-change film 17 is formed by a manufacturing process such as a sputtering method that provides a low coverage.

A method of manufacturing a resistance-change memory according to the sixth embodiment is described below by way of example with reference to the drawings. The manufacturing process is the same as that in the first embodiment up to the formation of a hard mask layer 21. It is to be noted that the area of the formed hard mask layer 21 is smaller than that in the first embodiment.

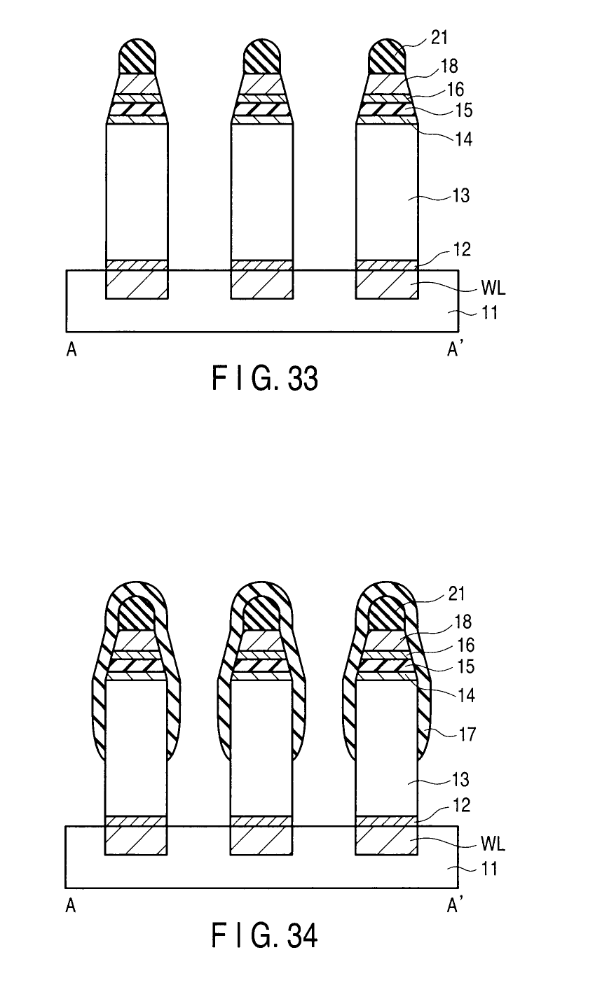

Then, as shown in FIG. 33, using the hard mask layers 21 as a mask, a laminated structure comprising a barrier film 12, a diode 13, the lower electrode 14, the insulating film 15, the upper electrode 16 and a stopper layer 18 is processed into a pillar shape by, for example, the RIE method. Here, the laminated film comprising the lower electrode 14, the insulating film 15, the upper electrode 16 and the stopper layer 18 is tapered. That is, the laminated film is processed by a taper-etching method. Thus, the area of the upper electrode 16 is smaller than the area of the lower electrode 14. On the other hand, the side surface of a laminated film comprising the barrier film 12 and the diode 13 is processed to be substantially perpendicular. Such a shape is obtained by controlling reaction products and etching bias in the RIE process.

Then, as shown in FIG. 34, the resistance-change films 17 are formed by the sputtering method. When the resistance-change films 17 are formed by the sputtering method, its coverage is generally low, and the film is not easily formed on the side surface of the pillar. However, in this embodiment, the laminated film comprising the lower electrode 14, the insulating film 15 and the upper electrode 16 is tapered, and the resistance-change film 17 is therefore formed on at least the side surface of the laminated film. That is, the resistance-change film 17 is formed to cover the pillar from its upper portion to middle portion. On the other hand, the resistance-change film 17 is not formed on the lower portion of the pillar.

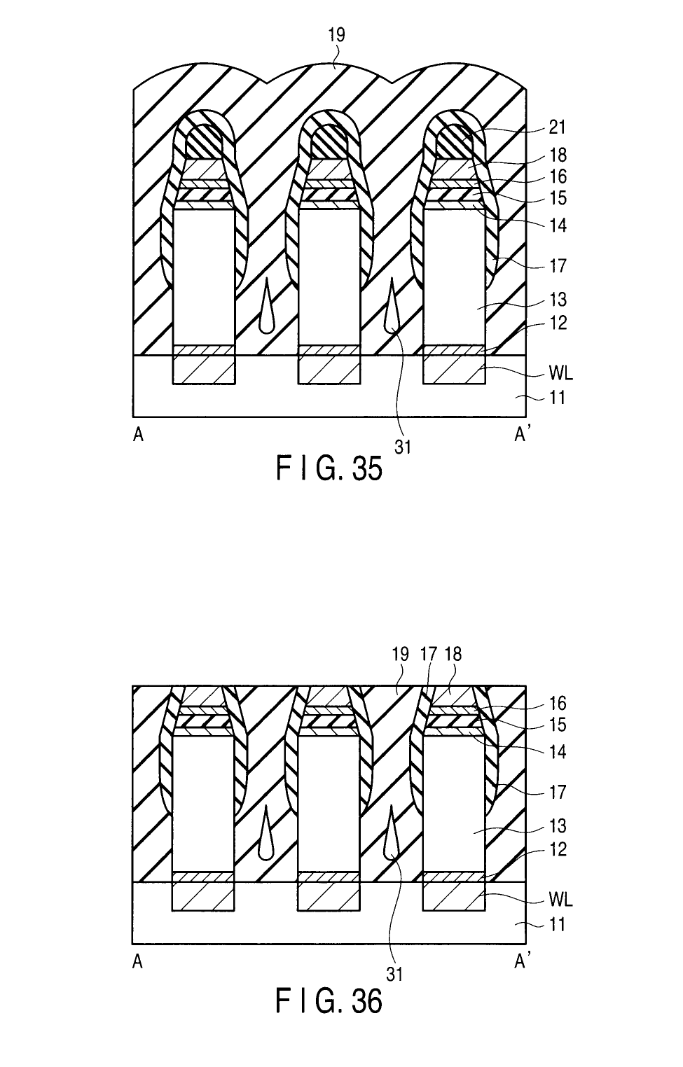

Then, as shown in FIG. 35, an interlayer insulating layer 19 is deposited on the entire surface of the device by, for example, the CVD method to fill the space between pillars. At the same time, a void 31 is formed in the interlayer insulating layer 19 between the lower portions of the pillars because the distance between the upper portions of the pillars is different from the distance between the lower portions of the pillars. Moreover, the upper portion of the pillar is tapered, so that the interlayer insulating layer 19 is easily buried into the upper portion of the pillar. This promotes the formation of the void 31 in the interlayer insulating layer 19.

Then, as shown in FIG. 36, using stopper layers 18 as a CMP stopper, the hard mask layers 21 are chipped off by the CMP method, thereby exposing the upper surfaces of the stopper layers 18. Thus, the upper surfaces of the memory cells MC and the upper surface of the interlayer insulating layer 19 are planarized.

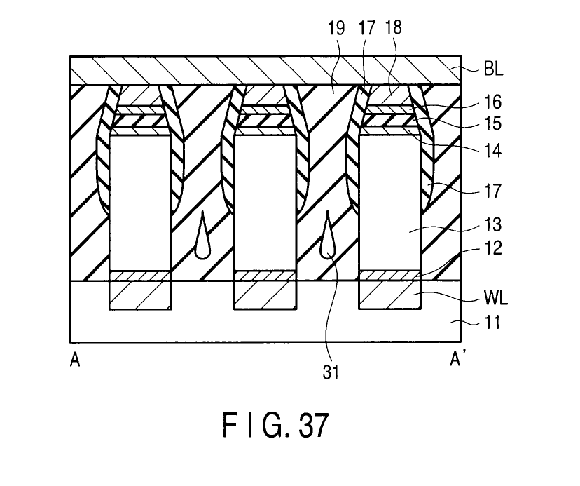

Then, as shown in FIG. 37, a material for upper wiring layers (bit lines BL) is deposited on the memory cells MC and the interlayer insulating layer 19. Then, the bit lines BL are processed into a linear shape by lithography and the RIE method. In this way, the resistance-change memory according to the sixth embodiment is manufactured.

As has been described above in detail, according to the sixth embodiment, the resistance-change film 17 can be formed by the sputtering method. In this case, the laminated film comprising the lower electrode 14, the insulating film 15 and the upper electrode 16 is tapered. This ensures that the resistance-change film 17 can be formed on the side surface of the laminated film.

Furthermore, the void 31 is formed between the memory cells MC. This void 31 is highly insulative and can therefore inhibit the thermal and electrical interference of the memory cells MC. As a result, a resistance-change memory with reduced failure and malfunctioning can be configured even when the density of the memory cells is high.

In addition, the configuration and manufacturing method according to the second embodiment can be applied to the third to sixth embodiments.

Although the diode 13 and the variable resistance element VR are stacked in this order to configure the memory cell MC in the first to fourth embodiments, the diode 13 and the variable resistance element VR may be laminated in reverse order. The laminating order in this case is as follows: the word line WL, the lower electrode 14, the insulating film 15, the upper electrode 16, the diode 13, the barrier film 12, the stopper layer 18 and the bit line BL. In this configuration, the stopper layer 18 may be omitted, and the barrier film 12 may double as the stopper layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A resistance-change memory comprising:
a laminated structure in which a lower electrode, an insulating film and an upper electrode are stacked; and
a resistance-change film provided on a side surface of the laminated structure, and configured to store data in accordance with an electric resistance change.

2. The memory of claim 1, wherein the resistance-change film is lower in dielectric breakdown voltage than the insulating film.

3. The memory of claim 1, wherein a thickness of the resistance-change film is less than half a distance between adjacent laminated structures.

4. The memory of claim 1, further comprising:
first and second lines intersecting with each other; and
a memory cell connected between the first line and the second line,
wherein the memory cell comprises a variable resistance element and a selection element connected in series, and
the variable resistance element is configured by the laminated structure and the resistance-change film.

5. The memory of claim 4, wherein the selection element is a diode.

6. The memory of claim 5, wherein
the laminated structure is provided on the diode, and
the resistance-change film is provided higher than a middle portion of the diode.

7. The memory of claim 1, wherein at least one of the lower electrode and the upper electrode is crystallized.

8. The memory of claim 7, wherein the resistance-change film has the same crystalline orientation as the crystallized electrode.

9. The memory of claim 8, wherein the resistance-change film has a crystalline orientation in an in-plane direction.

10. The memory of claim 1, further comprising a crystal film provided on a side surface of the resistance-change film, and configured to control a crystalline orientation of the resistance-change film.

11. The memory of claim 1, further comprising an interlayer insulating layer provided between adjacent laminated structures, and having a void.

12. The memory of claim 1, wherein the laminated structure is tapered.

13. A method of manufacturing a resistance-change memory, the method comprising:
forming first lines in an insulating layer;
depositing, on the first lines, a first material of selection elements, and a second material of laminated structures in each which a lower electrode, an insulating film and an upper electrode are stacked;
processing the first material and the second material to form pillars on the first lines;
forming, on side surfaces of the laminated structures, resistance-change films which store data in accordance with an electric resistance change;
forming an interlayer insulating layer between the pillars; and
forming, on the pillars, second lines which intersect with the first lines.

14. The method of claim 13, wherein the resistance-change film is formed higher than a middle portion of the selection element.

15. The method of claim 13, wherein the resistance-change films cover circumferential surfaces of the laminated structures.

16. The method of claim 13, wherein the laminated structures are tapered.

17. The method of claim 13, wherein the interlayer insulating layer has a void.

18. The method of claim 13, further comprising forming, on the side surfaces of the resistance-change films, crystal films which control crystalline orientations of the resistance-change films.

19. The method of claim 13, wherein the selection elements are diodes.
